(19) United States
(12) Patent Application Publication
(10) Pub. No.: US 2024/0297581 A1
(43) Pub. Date: Sep. 5, 2024

(54) POWER STAGE CIRCUIT WITH PULL-DOWN CIRCUITRY FOR REDUCING POWER LOSSES

(71) Applicant: TEXAS INSTRUMENTS INCORPORATED, Dallas, TX (US)

(72) Inventors: Manojit Chakraborty, Bangalore (IN); Rejin Kanjavalappil Raveendranath, Bangalore (IN)

(21) Appl. No.: 18/524,005

(22) Filed: Nov. 30, 2023

(30) Foreign Application Priority Data
Mar. 2, 2023 (IN) 202341013980

(51) Int. Cl. H02M 3/155

(52) U.S. Cl. CPC H02M 3/155

(57) ABSTRACT

A circuit includes a first transistor, a second transistor, a third transistor, a fourth transistor, and a fifth transistor. A first terminal of the second transistor is coupled to a control terminal of the first transistor. A second terminal of the second transistor is coupled to a second terminal of the first transistor. A first terminal of the third transistor is coupled to a voltage supply terminal. A second terminal of the third transistor and a first terminal of the fourth transistor are coupled to a control terminal of the second transistor. A second terminal of the fourth transistor is coupled to the second terminal of the second transistor. A first terminal of the fifth transistor is coupled to a first terminal of the first transistor. A second terminal of the fifth transistor is coupled to a control terminal of the fourth transistor.

### REFERENCE TO RELATED APPLICATION

This application claims the benefit of India Provisional Application No. 202341013980, filed on Mar. 2, 2023, the contents of which are hereby incorporated by reference in their entirety.

### BACKGROUND

Direct current (DC)-to-DC converters and alternating current (AC)-to-DC converters, which may be referred to collectively as power converters, are widely employed in devices of today to perform power conversion. Generally, power converters receive a nominal voltage from a power source, such as a battery, and provide a regulated output voltage at one or more voltage levels. A variety of power converters and topologies can be employed to perform this power conversion. For example, buck converters, boost converters, and buck-boost converters are three basic types of power converter technologies.

### SUMMARY

In one example, a circuit includes a first transistor, a second transistor, a third transistor, a fourth transistor, and a fifth transistor. The first transistor has a first terminal, a second terminal, and a control terminal. The second transistor has a first terminal, a second terminal, and a control terminal. The first terminal of the second transistor is coupled to the control terminal of the first transistor. The second terminal of the second transistor is coupled to the second terminal of the first transistor. The third transistor has a first terminal, a second terminal, and a control terminal. The first terminal of the third transistor is coupled to a voltage supply terminal. The second terminal of the third transistor is coupled to the control terminal of the second transistor. The fourth transistor has a first terminal, a second terminal, and a control terminal. The first terminal of the fourth transistor is coupled to the control terminal of the second transistor. The second terminal of the fourth transistor is coupled to the second terminal of the second transistor. The fifth transistor has a first terminal, a second terminal, and a control terminal. The first terminal of the fifth transistor is coupled to the first terminal of the first transistor. The second terminal of the fifth transistor is coupled to the control terminal of the fourth transistor.

In one example, a circuit includes a transistor, a transistor driver, and pull-down circuitry. The transistor has a first terminal, a second terminal, and a control terminal. The transistor driver couples the control terminal of the transistor to a voltage supply terminal along a first path in response to a control signal transitioning from a first level to a second level. The transistor driver couples the control terminal of the transistor to the second terminal of the transistor along a second path in response to the control signal transitioning from the second level to the first level. The pull-down circuitry couples the control terminal of the transistor to the second terminal of the transistor along a third path in response to the control signal transitioning from the second level to the first level. The pull-down circuitry senses a voltage difference between a voltage at the first terminal of the transistor and a voltage at the second terminal of the transistor. The pull-down circuitry decouples the control terminal of the transistor from the second terminal of the transistor along the third path in response to the voltage difference reaching a threshold.

In one example, a circuit includes a first transistor, a first transistor driver, a second transistor, a second transistor driver, and pull-down circuitry. The first transistor has a first terminal, a second terminal, and a control terminal. The first transistor driver has a first terminal, a second terminal, a third terminal, and a control terminal. The first terminal of the first transistor driver is coupled to a first voltage supply terminal. The second terminal of the first transistor driver is coupled to the control terminal of the first transistor. The third terminal of the first transistor driver is coupled to the second terminal of the first transistor. The second transistor has a first terminal, a second terminal, and a control terminal. The first terminal of the second transistor is coupled to the second terminal of the first transistor. The second transistor driver has a first terminal, a second terminal, a third terminal, and a control terminal. The first terminal of the second transistor driver is coupled to a second voltage supply terminal. The second terminal of the second transistor driver is coupled to the control terminal of the second transistor. The third terminal of the second transistor driver is coupled to the second terminal of the second transistor. The pull-down circuitry has a first terminal, a second terminal, a first control terminal, and a second control terminal. The first terminal of the pull-down circuitry is coupled to the control terminal of the second transistor. The second terminal of the pull-down circuitry is coupled to the second terminal of the second transistor. The first control terminal of the pull-down circuitry is coupled to the control terminal of the second transistor driver. The second control terminal of the pull-down circuitry is coupled to the first terminal of the second transistor.

### BRIEF DESCRIPTION OF THE DRAWINGS

FIG. 1 is a circuit diagram of some examples of a power stage circuit.

FIG. 2 is a circuit diagram of some other examples of a power stage circuit.

FIG. 3 is a flow diagram of some examples of the operation of the power stage circuit of FIG. 2.

FIG. 4 is a timing diagram of some examples of the operation of the power stage circuit of FIG. 2.

FIG. 5 and FIG. 6 are circuit diagrams of some other examples of a power stage circuit.

FIG. 7 is a flow diagram of some examples of the operation of the power stage circuit of FIG. 6.

FIG. 8 is a timing diagram of some examples of the operation of the power stage circuit of FIG. 6.

FIG. 9 is a circuit diagram of some examples of a power converter circuit including the power stage circuit of FIG. 5.

FIG. 10 is a circuit diagram of some examples of a power converter system including the power converter circuit of FIG. 9.

FIG. 11 is a circuit diagram of some other examples of a power stage circuit.

FIG. 12 is a circuit diagram of some examples of a power converter system including the power stage circuit of FIG. 11.

The drawings are not necessarily to scale. Generally, the same reference numbers (or other reference designators) in the drawing(s) and this description refer to the same or similar (functionally and/or structurally) features.

### DETAILED DESCRIPTION

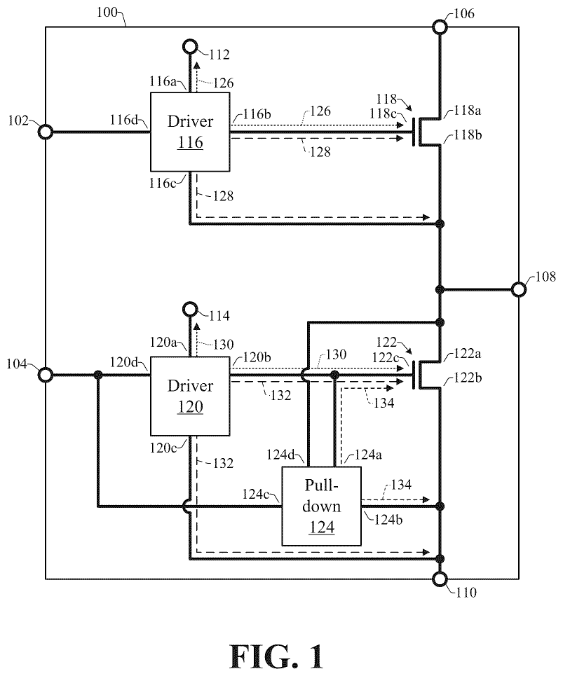

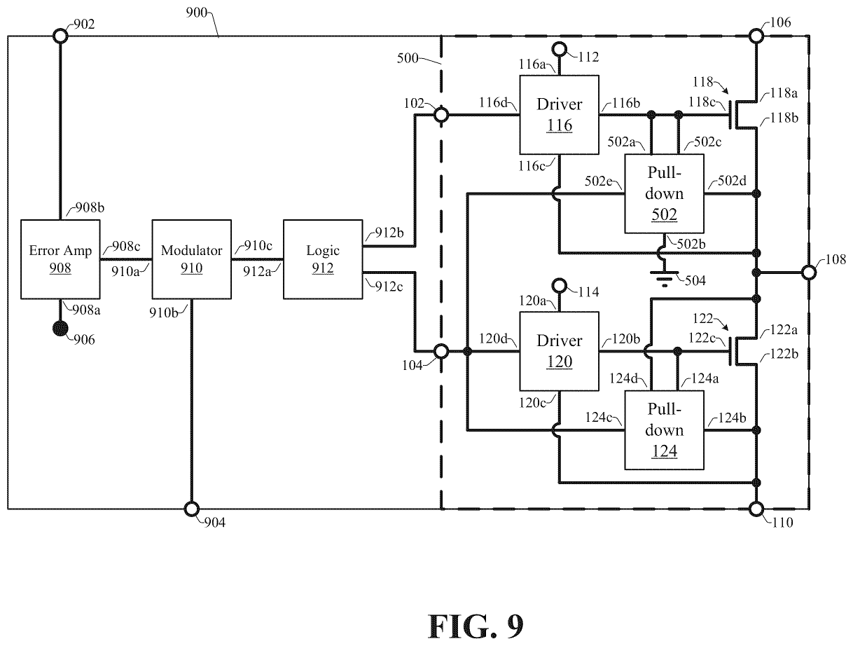

FIG. 1 is a circuit diagram of some examples of a power stage circuit 100. Circuit 100 has a first control terminal 102, a second control terminal 104, a first terminal 106, a second terminal 108, a third terminal 110, a first voltage supply terminal 112, and a second voltage supply terminal 114. Circuit 100 includes a first transistor driver 116, a first transistor 118, a second transistor driver 120, and a second transistor 122. In some examples, circuit 100 is a power stage of a DC-to-DC converter (as described in further detail with reference to FIG. 9).

Transistor 118 has a first terminal 118a, a second terminal 118b, and a control terminal 118c. Terminal 118a of transistor 118 is coupled to terminal 106. Terminal 118b of transistor 118 is coupled to terminal 108.

Transistor driver 116 has a first terminal 116a, a second terminal 116b, a third terminal 116c, and a control terminal 116d. Terminal 116a of transistor driver 116 is coupled to voltage supply terminal 112. Terminal 116b of transistor driver 116 is coupled to the control terminal 1l8c of transistor 118. Terminal 116c of transistor driver 116 is coupled to terminal 118b of transistor 118.

Transistor 122 has a first terminal 122a, a second terminal 122b, and a control terminal 122c. Terminal 122a of transistor 122 is coupled to terminal 118b of transistor 118 and terminal 108. Terminal 122b of transistor 122 is coupled to terminal 110.

Transistor driver 120 has a first terminal 120a, a second terminal 120b, a third terminal 120c, and a control terminal 120d. Terminal 120a of transistor driver 120 is coupled to voltage supply terminal 114. Terminal 120b of transistor driver 120 is coupled to the control terminal 122c of transistor 122. Terminal 120c of transistor driver 120 is coupled to terminal 122b of transistor 122.

Transistor driver 116 selectively couples the control terminal 118c of transistor 118 to voltage supply terminal 112 along a pull-up path 126 in response to a control signal at control terminal 102 transitioning from a first level (e.g., a HIGH level) to a second level (e.g., a LOW level). In response to transistor driver 116 coupling the control terminal 18c of transistor 118 to voltage supply terminal 112 along the pull-up path 126, transistor 118 turns ON (terminal 118a is coupled to terminal 118b so that current can flow through transistor 118). Transistor driver 116 selectively couples the control terminal 118c of transistor 118 to terminal 118b of transistor 118 along a pull-down path 128 in response to the control signal at control terminal 102 transitioning from the second level (e.g., the LOW level) to the first level (e.g., the HIGH level). In response to transistor driver 116 coupling the control terminal 118c of transistor 118 to terminal 118b of transistor 118 along the pull-down path 128, transistor 118 turns OFF (terminal 118a is decoupled from terminal 118b so that current cannot flow through transistor 118).

Similarly, transistor driver 120 selectively couples the control terminal 122c of transistor 122 to voltage supply terminal 114 along a pull-up path 130 in response to a control signal at control terminal 104 transitioning from the first level (e.g., the HIGH level) to the second level (e.g., the LOW level). In response to transistor driver 120 coupling the control terminal 122c of transistor 122 to voltage supply terminal 114 along the pull-up path 130, transistor 122 turns ON. Transistor driver 120 selectively couples the control terminal 122c of transistor 122 to terminal 122b of transistor 122 along a pull-down path 132 in response to the control signal at control terminal 104 transitioning from the second level (e.g., the LOW level) to the first level (e.g., the HIGH level). In response to transistor driver 120 coupling the control terminal 122c of transistor 122 to terminal 122b of transistor 122 along the pull-down path 132, transistor 122 turns OFF.

Transistors 118, 122 are operated in a complementary fashion. For example, when transistor 122 is turned ON, transistor 118 is turned OFF. Further, when transistor 122 is turned OFF, transistor 118 is turned ON. In some examples, transistor 118 and transistor 122 are N-channel metal-oxide-semiconductor field effect transistors (MOSFETs).

A challenge with circuit 100 is that switching losses occur when transistors 118, 122 transition between ON and OFF. For example, power is consumed by transistor 122 while transistor 122 is turning OFF. The longer it takes for transistor 122 to turn OFF, the greater the power loss. This power loss reduces the efficiency of circuit 100 and the maximum output power of circuit 100. Thus, in various examples of the present description, circuit 100 further includes pull-down circuitry 124 to reduce the turn-off time of transistor 122 (increase the turn-off speed of transistor 122), thereby reducing switching losses, improving efficiency, and improving maximum output power.

Pull-down circuitry 124 has a first terminal 124a, a second terminal 124b, a first control terminal 124c, and a second control terminal 124d. Terminal 124a of pull-down circuitry 124 is coupled to control terminal 122c of transistor 122. Terminal 124b of pull-down circuitry 124 is coupled to terminal 122b of transistor 122. Control terminal 124c of pull-down circuitry 124 is coupled to control terminal 120d of transistor driver 120. Control terminal 124d of pull-down circuitry 124 is coupled to terminal 122a of transistor 122.

Pull-down circuitry 124 selectively couples the control terminal 122c of transistor 122 to terminal 122b of transistor 122 along an additional pull-down path 134 in response to the control signal at terminal 104 transitioning from the second level (e.g., the LOW level) to the first level (e.g., the HIGH level). The additional pull-down path 134 reduces the total resistance between the control terminal 122c and terminal 122b. Reducing the total resistance between the control terminal 122c and terminal 122b can reduce the amount of time it takes for transistor 122 to turn OFF (the turn-off time of transistor 122). Reducing the turn-off time of transistor 122 can reduce the power consumed by transistor 122 during turn OFF. As a result, the efficiency and the maximum output power of circuit 100 can be improved.

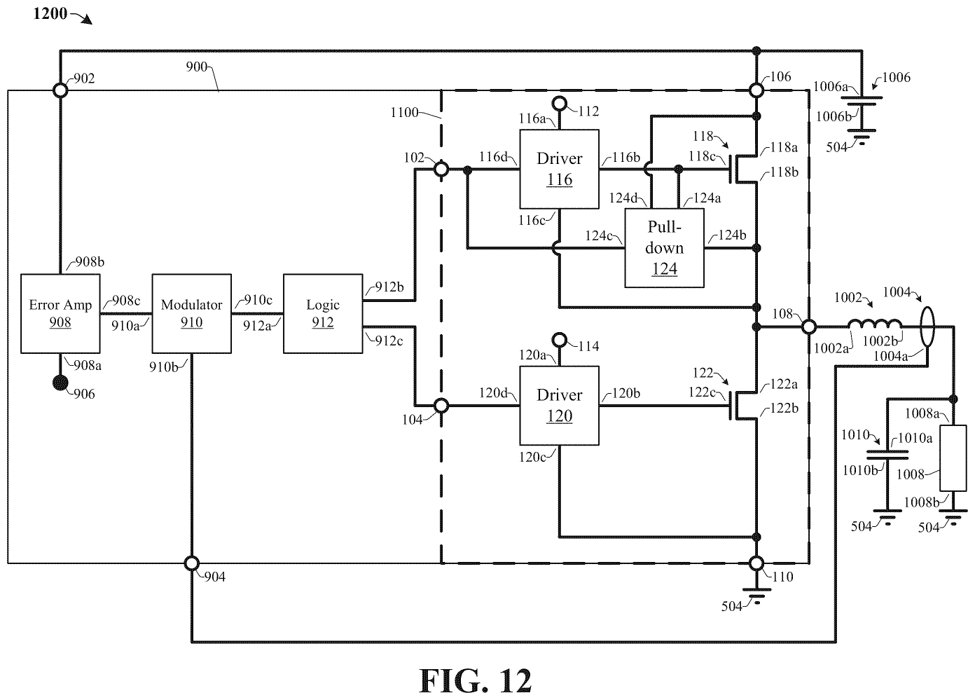

However, in some cases, transistor 122 can be damaged if the turn-off speed is too fast. For example, when circuit 100 is coupled to external components (e.g., as shown in FIG. 12 and FIG. 12), parasitic inductance(s) may be present in the system. These parasitic inductance(s) may increase the voltage across transistor 122 during turn-off. In some cases, the faster the turn-off of transistor 122, the higher the voltage across transistor 122 due to these parasitic inductance(s). Consequently, in some cases, the turn-off speed of transistor 122 may be fast enough to cause the voltage across transistor 122 to be high enough to damage transistor 122. Thus, in various examples of the present description, pull-down circuitry 124 senses the voltage across transistor 122 (a voltage difference between a voltage at terminal 122a of transistor 122 and a voltage at terminal 122b of transistor 122) and selectively decouples the control terminal 122c of transistor 122 from terminal 122b of transistor 122 along the additional pull-down path 134 in response to the voltage across transistor 122 reaching a threshold. By decoupling the additional pull-down path 134 in response to the voltage across 122 reaching the threshold, the turn-off speed of transistor 122 can be reduced before the voltage across 122 gets high enough to damage transistor 122. Thus, damage to transistor 122 can be avoided and hence the reliability of circuit 100 can be improved.

In some examples, circuit 100 is included in a single integrated chip and/or a single package. In some circuits, to avoid damage to transistor 122, a transistor having a greater voltage rating is used in place of transistor 122. However, these higher rated transistors take up more area on the chip. Pull-down circuitry 124 uses less area on the chip than a transistor having a higher voltage rating while still maintaining the reliability of circuit 100.

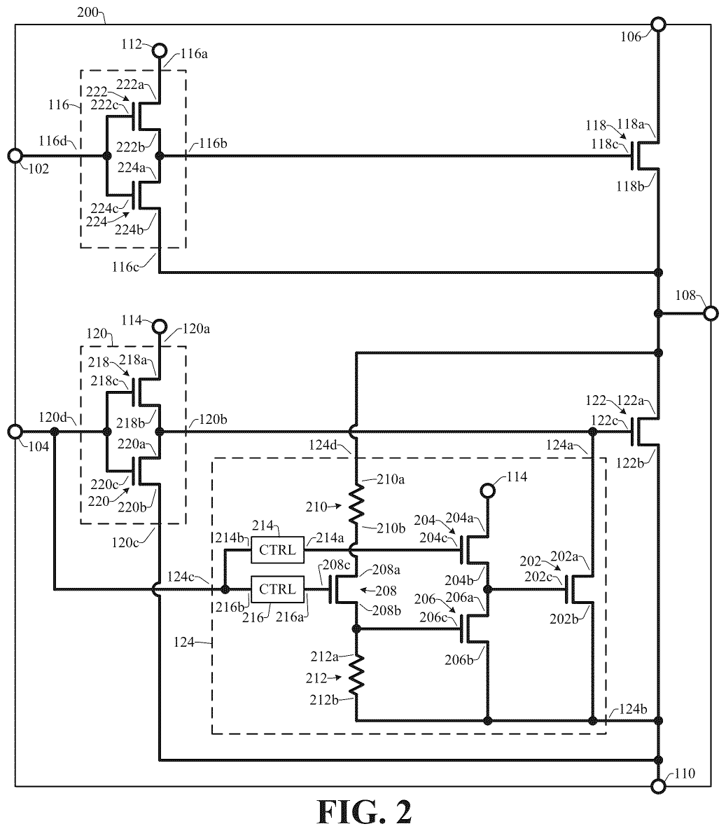

FIG. 2 is a circuit diagram of some examples of a power stage circuit 200 in which pull-down circuitry 124 includes a first transistor 202, a second transistor 204, a third transistor 206, a fourth transistor 208, a first resistor 210, a second resistor 212, first control circuitry 214, and second control circuitry 216. Circuit 200 of FIG. 2 is an example implementation of circuit 100 of FIG. 1.

Transistor 202 has a first terminal 202a coupled to the control terminal 122c of transistor 122. Transistor 202 has a second terminal 202b coupled to terminal 122b of transistor 122. Transistor 204 has a first terminal 204a coupled to voltage supply terminal 114. Transistor 204 has a second terminal 204b coupled to a control terminal 202c of transistor 202. Transistor 206 has a first terminal 206a coupled to the control terminal 202c of transistor 202. Transistor 206 has a second terminal 206b coupled to terminal 202b of transistor 202. Transistor 208 has a first terminal 208a coupled to terminal 122a of transistor 122. Transistor 208 has a second terminal 208b coupled to a control terminal 206c of transistor 206.

Resistor 210 has a first terminal 210a coupled to terminal 122a of transistor 122. Resistor 210 has a second terminal 210b coupled to terminal 208a of transistor 208. Resistor 212 has a first terminal 212a coupled to terminal 208b of transistor 208. Resistor 212 has a second terminal 212b coupled to terminal 122b of transistor 122.

Control circuitry 214 has a first terminal 214a coupled to a control terminal 204c of transistor 204. Control circuitry 214 has a second terminal 214b coupled to terminal 104. Control circuitry 216 has a first terminal 216a coupled to a control terminal 208c of transistor 208. Control circuitry 216 has a second terminal 216b coupled to control terminal 104. In some examples, control circuitry 214 is or includes a first pulse generator circuit and control circuitry 216 is or includes a second pulse generator circuit. The pulse generator circuits generate pulses (having controllable pulse widths) in response to transitions in the signal at terminals 214b, 216b. In some examples, a pulse generator circuit includes a first resistor, a second resistor, and a third resistor having first terminals coupled to a voltage supply terminal. A second terminal of the first resistor is coupled to a first terminal of a capacitor and a first terminal of a first transistor. A second terminal of the second resistor is coupled to a second terminal of the capacitor and a control terminal of a second transistor. A second terminal of the third resistor is coupled to a first terminal of the second transistor and to an output of the pulse generator circuit (terminal 214a for control circuitry 214; terminal 216a for control circuitry 216). A control terminal of the first transistor is coupled to an input of the pulse generator circuit (terminal 214b for control circuitry 214; terminal 216b for control circuitry 216). A second terminal of the first transistor and a second terminal of the second transistor are coupled to ground. The width of the pulse can be controlled by adjusting the capacitance of the capacitor and the resistance of the second resistor.

Transistor driver 120 includes a first transistor 218 and a second transistor 220. Transistor 218 has a first terminal 218a coupled to voltage supply terminal 114. Transistor 218 has a second terminal 218b coupled to the control terminal 122c of transistor 122. Transistor 218 has a control terminal 218c coupled to control terminal 104. Transistor 220 has a first terminal 220a coupled to the control terminal 122c of transistor 122. Transistor 220 has a second terminal 220b coupled to terminal 122b of transistor 122. Transistor 220 has a control terminal 220c coupled to control terminal 104.

Transistor driver 116 includes a first transistor 222 and a second transistor 224. Transistor 222 has a first terminal 222a coupled to voltage supply terminal 112. Transistor 222 has a second terminal 222b coupled to the control terminal 118c of transistor 118. Transistor 222 has a control terminal 222c coupled to control terminal 102. Transistor 224 has a first terminal 224a coupled to the control terminal 118c of transistor 118. Transistor 224 has a second terminal 224b coupled to terminal 118b of transistor 118. Transistor 224 has a control terminal 224c coupled to control terminal 102.

In some examples, transistor 118, transistor 122, transistor 202, transistor 206, transistor 208, transistor 220, and transistor 224 are N-channel MOSFETs. Further, transistor 204, transistor 218, and transistor 222 are P-channel MOSFETs.

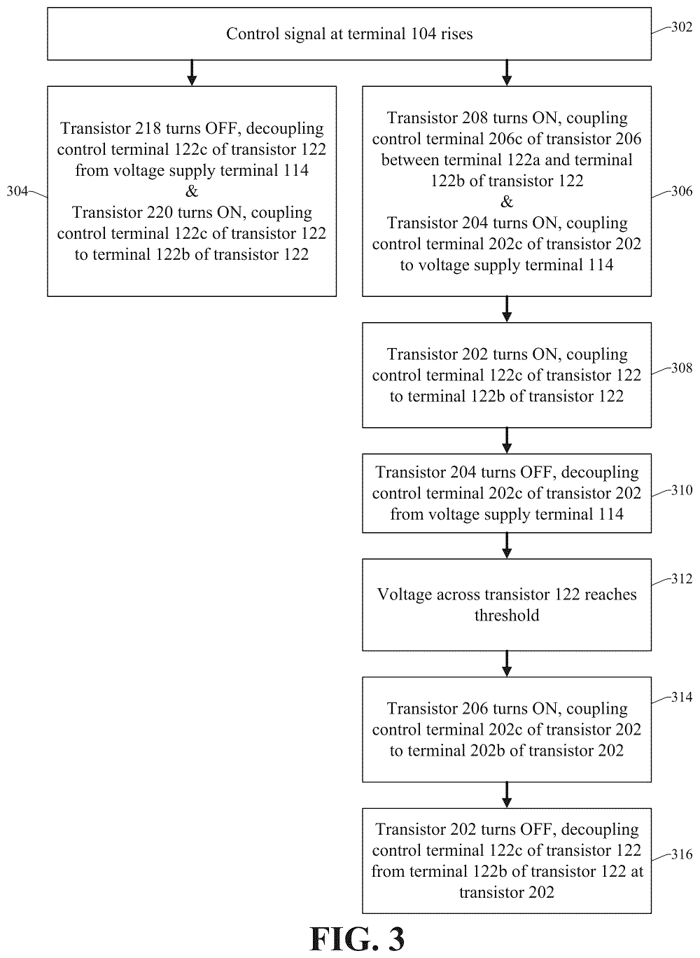

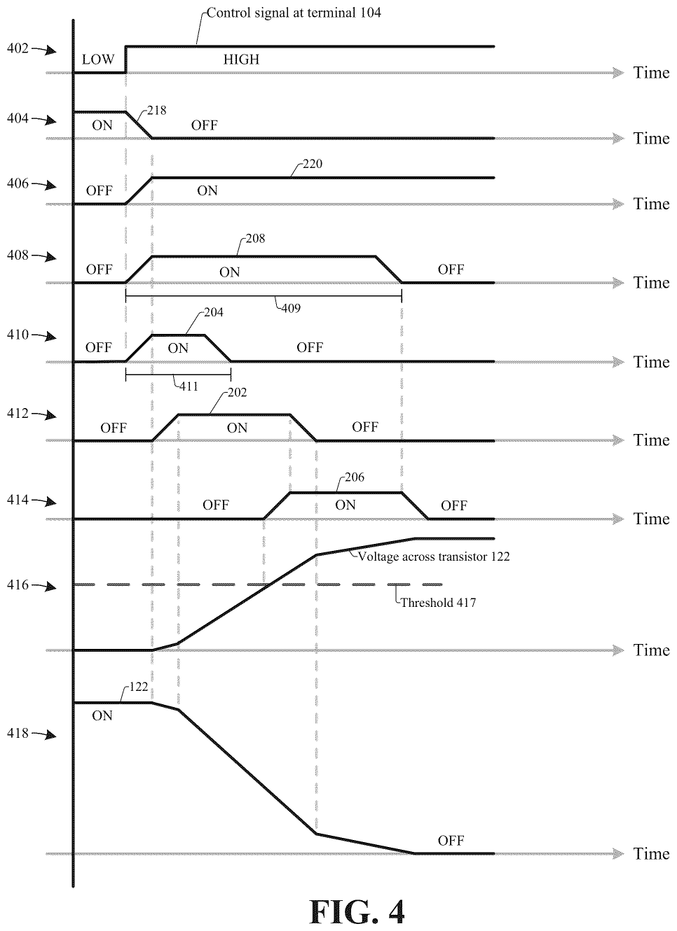

FIG. 3 is a flow diagram of some examples of the operation of circuit 200 of FIG. 2. FIG. 4 is a timing diagram of some examples of the operation of circuit 200 of FIG. 2.

At block 302, the control signal at control terminal 104 rises. For example, the control signal transitions from a LOW level (e.g., logic “0”) to a HIGH level (e.g., logic “1”), as shown at 402 of FIG. 4.

At block 304, in response to the control signal at control terminal 104 rising, transistor 218 turns OFF (as shown at 404 of FIG. 4), thereby decoupling the control terminal 122c of transistor 122 from voltage supply terminal 114. Further, at block 304, in response to the control signal at control terminal 104 rising, transistor 220 turns ON (as shown at 406 of FIG. 4), thereby coupling control terminal 122c of transistor 122 to terminal 122b of transistor 122. Thus, transistor 220 beings to pull down the control terminal 122c of transistor 122, which begins the process of turning transistor 122 OFF (as shown at 418 of FIG. 4). Consequently, the voltage across transistor 122 (the voltage difference between the voltage at terminal 122a and the voltage at terminal 122b) begins to rise (as shown at 416 of FIG. 4).

At block 306, in response to the control signal at control terminal 104 rising, transistor 208 turns ON (as shown at 408 of FIG. 4), thereby coupling the control terminal 206c of transistor 206 between terminal 122a and terminal 122b of transistor 122. As a result, pull-down circuitry 124 beings “sensing” the voltage across transistor 122. For example, in response to transistor 208 turning ON, a “sense” voltage that is proportional to the voltage across transistor 122 is present at the control terminal 206c of transistor 206. When this “sense” voltage is below the threshold voltage of transistor 206, transistor 206 remains OFF. In response to this “sense” voltage surpassing the threshold voltage of transistor 206, transistor 206 turns ON, as explained further below.

Transistor 208 turns ON for a first predetermined amount of time 409 in response to the control signal at control terminal 104 rising (as shown at 408 of FIG. 4). The first predetermined amount of time 409 is set by control circuitry 216. The first predetermined amount of time 409 is set to be long enough for the “sense” voltage to surpass the threshold voltage of transistor 206 (long enough for the voltage across transistor 122 to reach threshold 417). In some examples, the first predetermined amount of time 409 is approximately 15 nanoseconds, 20 nanoseconds, 25 nanoseconds, or some other suitable time.

Further, at block 306, in response to the control signal at control terminal 104 rising, transistor 204 turns ON, thereby coupling control terminal 202c of transistor 202 to voltage supply terminal 114. Transistor 204 turns ON for a second predetermined amount of time 411 in response to the control signal at control terminal 104 rising (as shown at 410 of FIG. 4). The second predetermined amount of time 411 is set by control circuitry 214. The second predetermined amount of time 411 is less than the first predetermined amount of time 409. In some examples, the second predetermined amount of time 411 is approximately 1 nanosecond, 2 nanoseconds, 3 nanoseconds, or some other suitable time.

At block 308, in response to transistor 204 turning ON (coupling the control terminal 202c of transistor 202 to voltage supply terminal 114), transistor 202 turns ON (as shown at 412 of FIG. 4), thereby coupling the control terminal 122c of transistor 122 to terminal 122b of transistor 122. Thus, transistor 202 also pulls down the control terminal 122c of transistor 122, which accelerates the process of turning transistor 122 OFF (as shown at 418 of FIG. 4). Consequently, the voltage across transistor 122 rises more quickly. By accelerating the turn-off of transistor 122, the power consumed by transistor 122 during turn-off can be reduced. Thus, efficiency can be improved.

At block 310, in response to the second predetermined amount of time 411 passing, transistor 204 turns OFF (as shown at 410 of FIG. 4), thereby decoupling the control terminal 202c of transistor 202 from voltage supply terminal 114. In response, the control terminal 202c of transistor 202 “floats” (the voltage at the control terminal 202c of transistor 202 remains approximately equal to the voltage at voltage supply terminal 114) so transistor 202 remains ON (as shown at 412 of FIG. 4).

At block 312, the voltage across transistor 122 (the voltage difference between the voltage at terminal 122a and the voltage at terminal 122b of transistor 122) reaches a threshold 417 (as shown at 416 of FIG. 4). In some examples, the threshold 417 is 50% greater than the threshold voltage of transistor 206, or some other suitable value.

At block 314, in response to the voltage across transistor 122 reaching the threshold 417, transistor 206 turns ON (as shown at 414 of FIG. 4), thereby coupling the control terminal 202c of transistor 202 to terminal 202b of transistor 202. As described above, pull-down circuitry 124 “senses” the voltage across transistor 122 has reached the threshold 417. For example, the voltage at the control terminal 206c of transistor 206 is proportional to the voltage across transistor 122. In response to the voltage at the control terminal 206c of transistor 206 surpassing the threshold voltage of transistor 206, transistor 206 turns ON.

At block 316, in response to transistor 206 turning ON (coupling control terminal 202c of transistor 202 to terminal 202b of transistor 202), transistor 202 turns OFF (as shown at 412 of FIG. 4), thereby decoupling the control terminal 122c of transistor 122 from terminal 122b of transistor 122 at transistor 202. Thus, transistor 202 stops pulling down the control terminal 122c of transistor 122 when the voltage across transistor 122 becomes “high” (greater than or equal to the threshold 417). This decelerates the process of turning transistor 122 OFF (as shown at 418 of FIG. 4) which decreases the rate at which the voltage across transistor 122 rises. Thus, transistor 122 turns OFF slower when the voltage across transistor 122 becomes “high”, which may prevent the voltage across transistor 122 from becoming “too high” (high enough to damage transistor 122). As a result, the risk of damaging transistor 122 can be reduced.

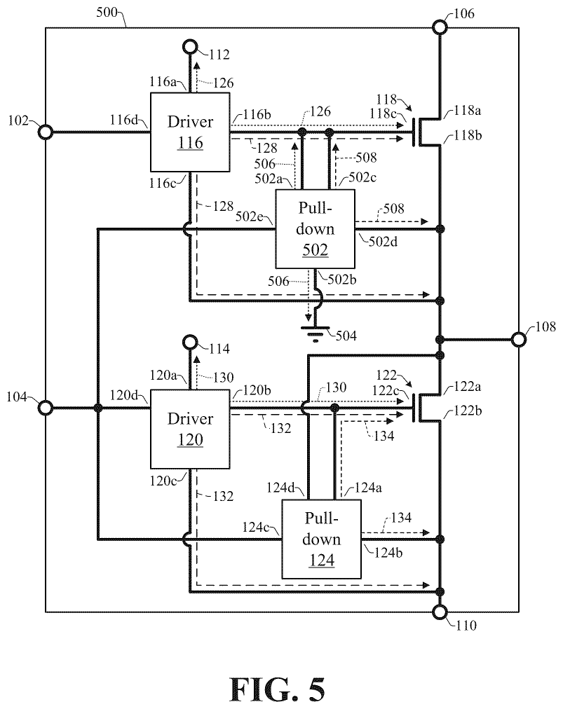

FIG. 5 is a circuit diagram of some examples of a power stage circuit 500 including pull-down circuitry 502 coupled to the control terminal 118c of transistor 118. When transitioning from transistor 118 being ON and transistor 122 being OFF to transistor 118 being OFF and transistor 122 being ON, transistor driver 116 turns transistor 118 OFF before transistor driver 120 turns transistor 122 ON to prevent “shoot-through” (terminal 106 being coupled to terminal 110). The time when both transistor 118 and transistor 122 are OFF is referred to as “deadtime”. As deadtime increases, the efficiency of circuit 500 decreases. In some circuits, the voltage at voltage supply terminal 112 experiences high variability, which may cause the turn-off of transistor 118 to vary and hence may cause deadtime to vary. Consequently, longer deadtime may be needed to avoid shoot-through. As a result, efficiency is reduced. Circuit 500 includes pull-down circuitry 502 to reduce variation in the turn-off of transistor 118 and hence reduce deadtime variation. Reducing deadtime variation reduces the need for lengthy deadtime. As a result, efficiency can be improved.

Pull-down circuitry 502 has a first terminal 502a, a second terminal 502b, a third terminal 502c, a fourth terminal 502d, and a control terminal 502e. Terminal 502a of pull-down circuitry 502 is coupled to control terminal 118c of transistor 118. Terminal 502b of pull-down circuitry 502 is coupled to ground 504. Terminal 502c of pull-down circuitry 502 is coupled to control terminal 118c of transistor 118. Terminal 502d of pull-down circuitry 502 is coupled to terminal 118b of transistor 118. Control terminal 502e of pull-down circuitry 502 is coupled to control terminal 104. Other circuit components of power stage circuit 500 and the coupling of those components are shown in and described with respect to FIG. 1.

Pull-down circuitry 502 selectively couples the control terminal 118c of transistor 118 to ground 504 along a pull-down path 506 in response to the control signal at terminal 104 falling (transitioning from a HIGH level to a LOW level). Further, pull-down circuitry 502 selectively couples the control terminal 118c of transistor 118 to terminal 118b of transistor 118 along another pull-down path 508 in response to the control signal at terminal 104 falling.

Because the control terminal 502e of pull-down circuitry 502 is coupled to control terminal 104, pull-down circuitry 502 operates independently of voltage supply terminal 112. Thus, the operation of pull-down circuitry 502 does not suffer from variability at voltage supply terminal 112. As a result, pull-down circuitry 502 can improve the consistency of the pull-down of the control terminal 118c of transistor 118. By improving this pull-down consistency, deadtime variation can be reduced. By reducing deadtime variation, total deadtime can be reduced without increasing risk of shoot-through. Thus, efficiency can be improved.

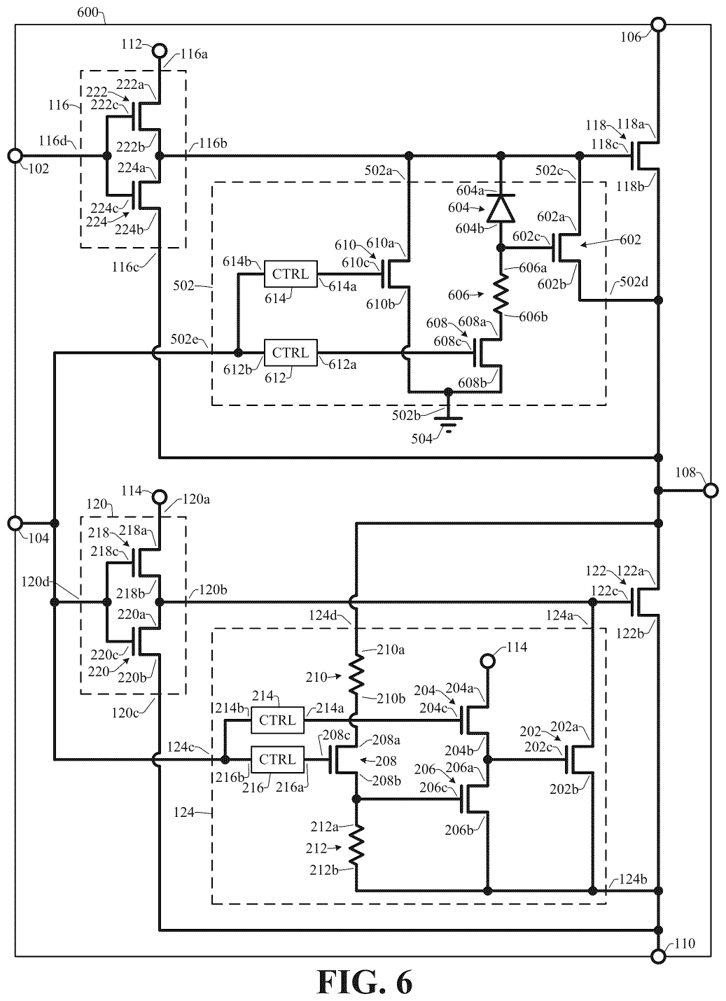

FIG. 6 is a circuit diagram of some examples of a power stage circuit 600 in which pull-down circuitry 502 includes a first transistor 602, a diode 604, a resistor 606, a second transistor 608, a third transistor 610, first control circuitry 612, and second control circuitry 614. Circuit 600 of FIG. 6 is an example implementation of circuit 500 of FIG. 5.

Transistor 602 has a first terminal 602a coupled to the control terminal 118c of transistor 118. Transistor 602 has a second terminal 602b coupled to terminal 118b of transistor 118. Diode 604 has a first terminal 604a (cathode) coupled to the control terminal 118c of transistor 118. Diode 604 has a second terminal 604b (anode) coupled to a control terminal 602c of transistor 602. Transistor 608 has a first terminal 608a coupled to the control terminal 602c of transistor 602. Transistor 608 has a second terminal 608b coupled to ground 504. Transistor 610 has a first terminal 610a coupled to the control terminal 118c of transistor 118. Transistor 610 has a second terminal 610b coupled to ground 504. Resistor 606 has a first terminal 606a coupled to control terminal 602c of transistor 602. Resistor 606 has a second terminal 606b coupled to terminal 608a of transistor 608.

Control circuitry 612 has a first terminal 612a coupled to a control terminal 608c of transistor 608. Control circuitry 612 has a second terminal 612b coupled to control terminal 104. Control circuitry 614 has a first terminal 614a coupled to a control terminal 610c of transistor 610. Control circuitry 614 has a second terminal 614b coupled to control terminal 104. In some examples, control circuitry 612 is or includes a first pulse generator circuit and control circuitry 614 is or includes a second pulse generator circuit. The pulse generator circuits generate pulses (having controllable pulse widths) in response to transitions in the signal at terminals 612b, 614b. Other circuit components of power stage circuit 600 and the coupling of those components are shown in and described with respect to FIG. 2.

In some examples, transistor 118, transistor 122, transistor 202, transistor 206, transistor 208, transistor 220, transistor 224, transistor 608, and transistor 610 are N-channel MOSFETs. Further, transistor 204, transistor 218, transistor 222, and transistor 602 are P-channel MOSFETs.

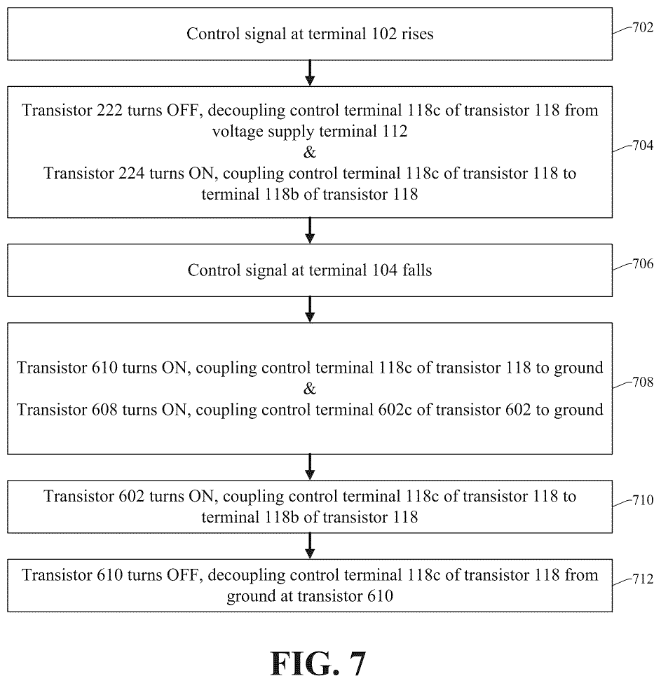

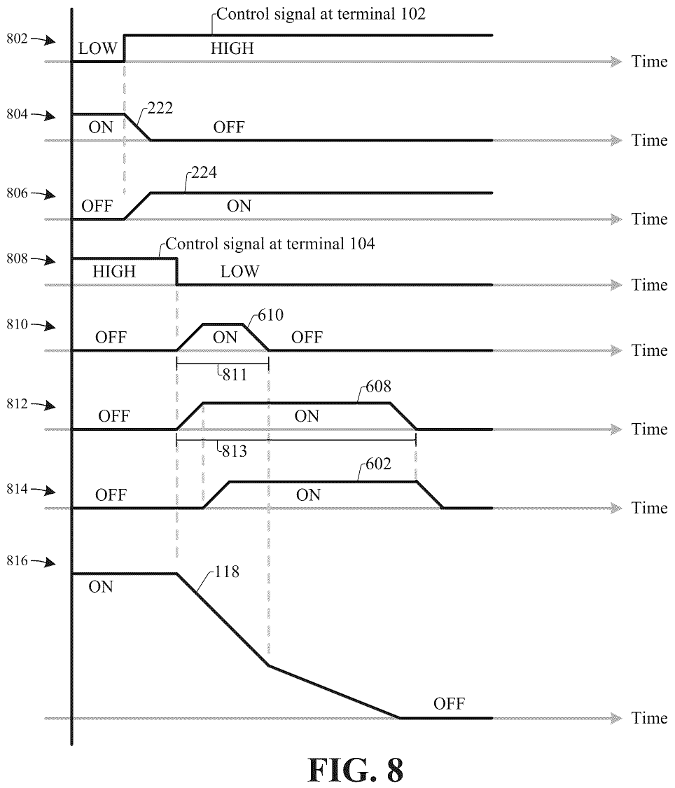

FIG. 7 is a flow diagram of some examples of the operation of circuit 600 of FIG. 6. FIG. 8 is a timing diagram of some examples of the operation of circuit 600 of FIG. 6.

At block 702, the control signal at terminal 102 rises (transitions from a LOW level to a HIGH level, as shown at 802 of FIG. 8). At block 704, in response to the control signal at terminal 102 rising, transistor 222 turns OFF (as shown at 804 of FIG. 8), thereby decoupling control terminal 118c of transistor 118 from voltage supply terminal 112. Further, at block 704, in response to the control signal at terminal 102 rising, transistor 224 turns ON (as shown at 806 of FIG. 8), thereby coupling control terminal 118c of transistor 118 to terminal 118b of transistor 118. Thus, transistor 224 beings to pull down the control terminal 118c of transistor 118, which begins the process of turning transistor 118 OFF (as shown at 816 of FIG. 8). At block 706, the control signal at terminal 104 falls (transitions from the HIGH level to the LOW level, as shown at 808 of FIG. 8).

At block 708, in response to the control signal at terminal 104 falling, transistor 610 turns ON (as shown at 810 of FIG. 8), thereby coupling the control terminal 118c of transistor 118 to ground. Thus, transistor 610 pulls down the control terminal 118c of transistor 118. This accelerates the pull-down of control terminal 118c when transistor 224 has already begun pulling down control terminal 118c. However, in some examples, transistor 224 may not have already begun pulling down control terminal 118c (due to variation at voltage supply terminal 112). In such examples, transistor 610 begins the pull down of control terminal 118c (in response to the control signal at terminal 104 falling). Thus, the variability of the pull down of control terminal 118c can be reduced. Consequently, deadtime variation can be reduced. By reducing deadtime variation, total deadtime can be reduced without increasing the risk of shoot-through. Thus, efficiency can be improved. Further, at block 708, in response to the control signal at terminal 104 falling, transistor 608 turns ON (as shown at 812 of FIG. 8), thereby coupling the control terminal 602c of transistor 602 to ground.

At block 710, in response to transistor 608 turning ON (coupling control terminal 602c to ground), transistor 602 turns ON (as shown at 814 of FIG. 8), thereby coupling control terminal 118c of transistor 118 to terminal 118b of transistor 118. Thus, transistor 602 also pulls down the control terminal 118c of transistor 118, which increases the speed of turning transistor 118 OFF.

At block 712, transistor 610 turns OFF, thereby decoupling control terminal 118c of transistor 118 from ground at transistor 610. Transistor 610 turns OFF after a predetermined amount of time 811 (as shown at 810 of FIG. 8). The predetermined amount of time 811 is set by control circuitry 614. The predetermined amount of time 811 is set to be relatively short to prevent damage to transistor 118 (due to the turn-off of transistor 118 being too fast). In some examples, the predetermined amount of time 811 is approximately 2 nanoseconds, 3 nanoseconds, 4 nanoseconds, or some other suitable time. Transistor 602 remains ON after transistor 610 turns OFF to maintain the pull-down of control terminal 118c.

Transistor 608 turns OFF after a predetermined amount of time 813. Transistor 602 turns OFF in response to transistor 608 turning OFF. The predetermined amount of time 813 is set by control circuitry 612. The predetermined amount of time 813 is long enough that transistor 224 turns ON before transistor 608 (and transistor 602) turns OFF, even if the turn-on of transistor 224 is delayed due to variation at voltage supply terminal 112. Thus, after transistor 608 (and transistor 602) turns OFF, transistor 224 maintains the pull-down of control terminal 118c.

FIG. 9 is a circuit diagram of some examples of a power converter circuit 900 (e.g., a DC-to-DC converter) including the power stage circuit 500 of FIG. 5. The power converter circuit 900 further includes an error amplifier 908, a modulator 910, and logic circuitry 912. The power converter has a first feedback terminal 902, a second feedback terminal 904, and a reference terminal 906.

The error amplifier 908 has a first input 908a coupled to reference terminal 906. The error amplifier 908 has a second input 908b of the error amplifier 908 is coupled to feedback terminal 902. The modulator 910 has a first input 910a coupled to an output 908c of the error amplifier 908. The modulator 910 has a second input 910b coupled to feedback terminal 904. The logic circuitry 912 has an input 912a coupled to an output 910c of the modulator 910. The logic circuitry 912 has a first output 912b coupled to the control terminal 116d of the first transistor driver 116. The logic circuitry 912 has a second output 912c coupled to the control terminal 120d of transistor driver 120.

The error amplifier 908 outputs an error signal based on a difference between a reference signal (e.g., a reference voltage) at the reference terminal 906 and a first feedback signal (e.g., a voltage feedback signal) at feedback terminal 902. The modulator 910 outputs a modulated signal based on the error signal at the output 908c and a second feedback signal (e.g., a current feedback signal) at feedback terminal 904. The logic circuitry 912 outputs a first control signal at output 912b and a second control signal at output 912c based on the modulated signal. In some examples, the first control signal is a delayed and inverted copy of the second control signal.

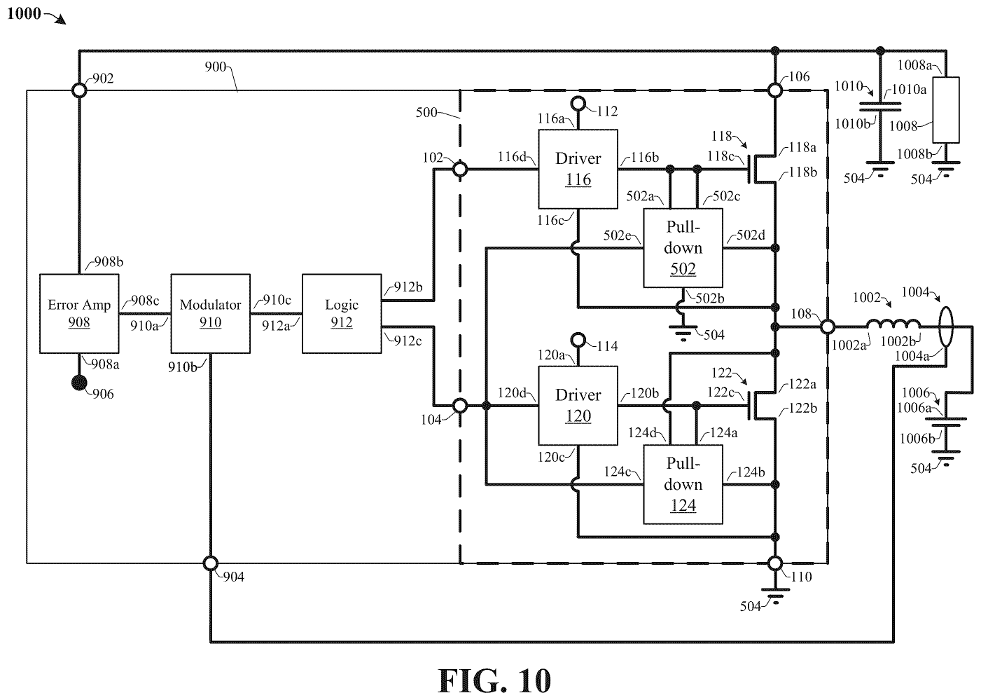

FIG. 10 is a circuit diagram of some examples of a power converter system 1000 including the power converter circuit 900 of FIG. 9. The system includes power converter circuit 900, an inductor 1002, a current sensor 1004, a voltage source 1006, a load 1008, and an output capacitor 1010. System 1000 is arranged in a “boost” configuration in the example shown in FIG. 10.

The inductor 1002 has a first terminal 1002a coupled to terminal 118b of transistor 118 and terminal 122a of transistor 122. The voltage source 1006 has a first terminal 1006a coupled to a second terminal 1002b of the inductor 1002. The voltage source 1006 has a second terminal 1006b coupled to ground 504. The current sensor 1004 is coupled between the inductor 1002 and the voltage source 1006. The current sensor 1004 has an output 1004a coupled to feedback terminal 904. The load 1008 has a first terminal 1008a coupled to terminal 118a of transistor 118 and feedback terminal 902. The load 10008 has a second terminal 1008b coupled to ground 504. The output capacitor 1010 has a first terminal 1010a coupled to terminal 118a of transistor 118 and feedback terminal 902. The output capacitor 1010 has a second terminal 1010b coupled to ground 504. Terminal 122b of transistor 122 is coupled to ground 504. In some examples, the load 1008 includes an amplifier (not shown) (e.g., a class-d amplifier) and a speaker (not shown) coupled to the amplifier.

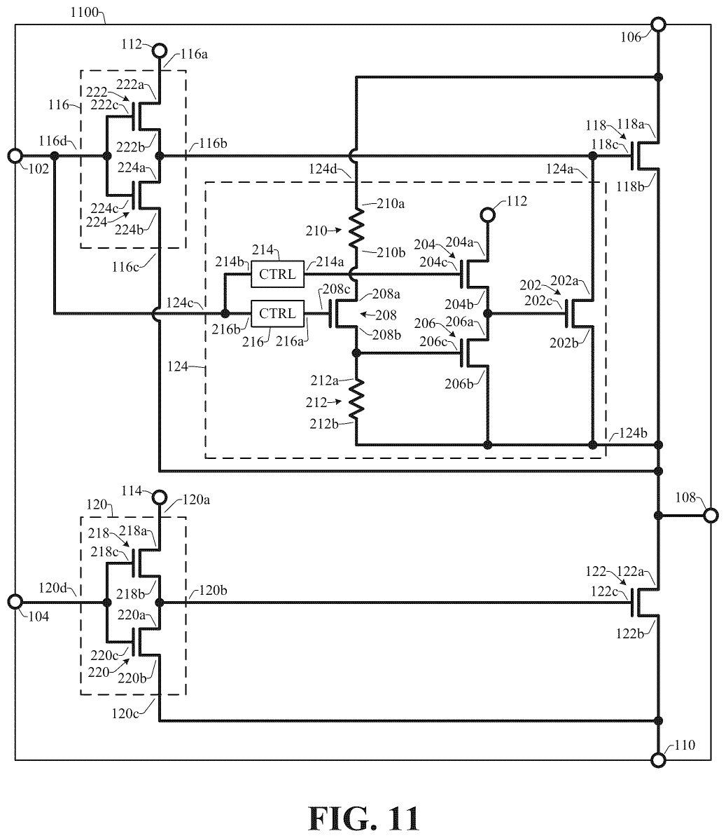

FIG. 11 is a circuit diagram of some examples of a power stage circuit 1100 in which pull-down circuitry 124 is coupled to the control terminal 118c of transistor 118 to reduce switching losses at transistor 118. Terminal 124a of pull-down circuitry 124 (and terminal 202a of transistor 202) is coupled to control terminal 118c of transistor 118. Terminal 124b of pull-down circuitry 124 (and terminal 202b of transistor 202, terminal 206b of transistor 206, and terminal 212b of resistor 212) is coupled to terminal 18b of transistor 118. Control terminal 124c of pull-down circuitry 124 (and terminal 214b of control circuitry 214 and terminal 216b of control circuitry 216) is coupled to terminal 102. Control terminal 124d of pull-down circuitry 124 (and terminal 210a of resistor 210) is coupled to terminal 118a of transistor 118.

In the example shown in FIG. 11, pull-down circuitry 124 selectively couples the control terminal 118c of transistor 118 to terminal 118b of transistor 118 in response to the control signal at terminal 102 transitioning from the second level (e.g., a LOW level) to the first level (e.g., a HIGH level). Pull-down circuitry 124 senses a voltage across transistor 118 (a voltage difference between a voltage at terminal 118a and a voltage at terminal 118b of transistor 118). Pull-down circuitry decouples the control terminal 118c of transistor 118 from terminal 118b of transistor 118 in response to the voltage across transistor 118 reaching a threshold to protect transistor 118 from damage.

FIG. 12 is a circuit diagram of some examples of a power converter system 1200 including the power stage circuit 1100 of FIG. 11. The system is arranged in a “buck” configuration in the example shown in FIG. 12.

Terminal 1006a of the voltage source 1006 is coupled to terminal 118a of transistor 118 and feedback terminal 902. Terminal 1008a of the load 1008 and terminal 1010a of the output capacitor 1010 are coupled to terminal 1002b of the inductor 1002.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero. Modifications are possible in the described examples, and other implementations are possible, within the scope of the claims.

What is claimed is:

1. A circuit comprising:
a first transistor having a first terminal, a second terminal, and a control terminal;
a second transistor having a first terminal, a second terminal, and a control terminal, the first terminal of the second transistor coupled to the control terminal of the first transistor, the second terminal of the second transistor coupled to the second terminal of the first transistor;
a third transistor having a first terminal, a second terminal, and a control terminal, the first terminal of the third transistor coupled to a voltage supply terminal, the second terminal of the third transistor coupled to the control terminal of the second transistor;
a fourth transistor having a first terminal, a second terminal, and a control terminal, the first terminal of the fourth transistor coupled to the control terminal of the second transistor, the second terminal of the fourth transistor coupled to the second terminal of the second transistor; and
a fifth transistor having a first terminal, a second terminal, and a control terminal, the first terminal of the fifth transistor coupled to the first terminal of the first transistor, the second terminal of the fifth transistor coupled to the control terminal of the fourth transistor.

2. The circuit of claim 1, further comprising:
first control circuitry having a first terminal and a second terminal, the first terminal of the first control circuitry coupled to the control terminal of the third transistor; and
second control circuitry having a first terminal and a second terminal, the first terminal of the second control circuitry coupled to the control terminal of the fifth transistor, the second terminal of the second control circuitry coupled to the second terminal of the first control circuitry.

3. The circuit of claim 2, further comprising:
a first resistor coupled between the first terminal of the first transistor and the first terminal of the fifth transistor; and
a second resistor having a first terminal and a second terminal, the first terminal of the second resistor coupled to the second terminal of the fifth transistor, the second terminal of the second resistor coupled to the second terminal of the first transistor.

4. The circuit of claim 3, further comprising:
a sixth transistor having a first terminal, a second terminal, and a control terminal, the first terminal of the sixth transistor coupled to the voltage supply terminal, the second terminal of the sixth transistor coupled to the control terminal of the first transistor; and
a seventh transistor having a first terminal, a second terminal, and a control terminal, the first terminal of the seventh transistor coupled to the control terminal of the first transistor, the second terminal of the seventh transistor coupled to the second terminal of the first transistor, the control terminal of the seventh transistor coupled to the control terminal of the sixth transistor and the second terminal of the second control circuitry.

5. The circuit of claim 4, further comprising:
an eighth transistor having a first terminal, a second terminal, and a control terminal, the second terminal of the eighth transistor coupled to the first terminal of the first transistor;
a nineth transistor having a first terminal, a second terminal, and a control terminal, the first terminal of the nineth transistor coupled to the control terminal of the eighth transistor, the second terminal of the nineth transistor coupled to the second terminal of the eighth transistor;
a diode having a first terminal and a second terminal, the first terminal of the diode coupled to the control terminal of the eighth transistor, the second terminal of the diode coupled to the control terminal of the nineth transistor;
a tenth transistor having a first terminal, a second terminal, and a control terminal, the first terminal of the tenth transistor coupled to the control terminal of the nineth transistor, the second terminal of the tenth transistor coupled to ground, the control terminal of the tenth transistor coupled to the control terminal of the nineth transistor; and
an eleventh transistor having a first terminal, a second terminal, and a control terminal, the first terminal of the eleventh transistor coupled to the control terminal of the eighth transistor, the second terminal of the eleventh transistor coupled to ground, the control terminal of the eleventh transistor coupled to control terminal of the nineth transistor.

6. The circuit of claim 5, further comprising:
first control circuitry having a first terminal and a second terminal, the first terminal of the first control circuitry coupled to the control terminal of the tenth transistor, the second terminal of the first control circuitry coupled to the control terminal of the nineth transistor; and
second control circuitry having a first terminal and a second terminal, the first terminal of the second control circuitry coupled to the control terminal of the eleventh transistor, the second terminal of the second control circuitry coupled to the control terminal of the nineth transistor.

7. The circuit of claim 6, further comprising:
a resistor coupled between the control terminal of the nineth transistor and the first terminal of the tenth transistor.

8. The circuit of claim 7, further comprising:
a twelfth transistor having a first terminal, a second terminal, and a control terminal, the first terminal of the twelfth transistor coupled to a second voltage supply terminal, the second terminal of the twelfth transistor coupled to the control terminal of the eighth transistor; and
a thirteenth transistor having a first terminal, a second terminal, and a control terminal, the first terminal of the thirteenth transistor coupled to the control terminal of the eighth transistor, the second terminal of the thirteenth transistor coupled to the second terminal of the eighth transistor, the control terminal of the thirteenth transistor coupled to the control terminal of the twelfth transistor.

9. A circuit comprising:
a transistor having a first terminal, a second terminal, and a control terminal;
a transistor driver configured to couple the control terminal of the transistor to a voltage supply terminal along a first path in response to a control signal transitioning from a first level to a second level and couple the control terminal of the transistor to the second terminal of the transistor along a second path in response to the control signal transitioning from the second level to the first level; and
pull-down circuitry configured to couple the control terminal of the transistor to the second terminal of the transistor along a third path in response to the control signal transitioning from the second level to the first level, sense a voltage difference between a voltage at the first terminal of the transistor and a voltage at the second terminal of the transistor, and decouple the control terminal of the transistor from the second terminal of the transistor along the third path in response to the voltage difference reaching a threshold.

10. The circuit of claim 9, wherein the transistor is a first transistor, the transistor driver is a first transistor driver, and the control signal is a first control signal, the circuit further comprising:
a second transistor having a first terminal, a second terminal, and a control terminal, the second terminal of the second transistor coupled to the first terminal of the first transistor; and
a second transistor driver configured to couple the control terminal of the second transistor to a second voltage supply terminal along a fourth path in response to a second control signal transitioning from the first level to the second level and couple the control terminal of the second transistor to the second terminal of the second transistor along a fifth path in response to the second control signal transitioning from the second level to the first level.

11. The circuit of claim 10, wherein the pull-down circuitry is first pull-down circuitry, the circuit further comprising:
second pull-down circuitry configured to couple the control terminal of the second transistor to ground along a sixth path in response to the first control signal transitioning from the first level to the second level and couple the control terminal of the second transistor to the second terminal of the second transistor along a seventh path in response to the first control signal transitioning from the first level to the second level.

12. A circuit comprising:
a first transistor having a first terminal, a second terminal, and a control terminal;
a first transistor driver having a first terminal, a second terminal, a third terminal, and a control terminal, the first terminal of the first transistor driver coupled to a first voltage supply terminal, the second terminal of the first transistor driver coupled to the control terminal of the first transistor, the third terminal of the first transistor driver coupled to the second terminal of the first transistor;
a second transistor having a first terminal, a second terminal, and a control terminal, the first terminal of the second transistor coupled to the second terminal of the first transistor;
a second transistor driver having a first terminal, a second terminal, a third terminal, and a control terminal, the first terminal of the second transistor driver coupled to a second voltage supply terminal, the second terminal of the second transistor driver coupled to the control terminal of the second transistor, the third terminal of the second transistor driver coupled to the second terminal of the second transistor; and
pull-down circuitry having a first terminal, a second terminal, a first control terminal, and a second control terminal, the first terminal of the pull-down circuitry coupled to the control terminal of the second transistor, the second terminal of the pull-down circuitry coupled to the second terminal of the second transistor, the first control terminal of the pull-down circuitry coupled to the control terminal of the second transistor driver, the second control terminal of the pull-down circuitry coupled to the first terminal of the second transistor.

13. The circuit of claim 12, wherein the pull-down circuitry includes:
a third transistor having a first terminal, a second terminal, and a control terminal, the first terminal of the third transistor coupled to the control terminal of the second transistor, the second terminal of the third transistor coupled to the second terminal of the second transistor;
a fourth transistor having a first terminal, a second terminal, and a control terminal, the first terminal of the fourth transistor coupled to the second voltage supply terminal, the second terminal of the fourth transistor coupled to the control terminal of the third transistor;
a fifth transistor having a first terminal, a second terminal, and a control terminal, the first terminal for the fifth transistor coupled to the control terminal of the third transistor, the second terminal of the fifth transistor coupled to the second terminal of the third transistor; and
a sixth transistor having a first terminal, a second terminal, and a control terminal, the first terminal of the sixth transistor coupled to the first terminal of the second transistor, the second terminal of the sixth transistor coupled to the control terminal of the fifth transistor.

14. The circuit of claim 13, further comprising:
first control circuitry having a first terminal and a second terminal, the first terminal of the first control circuitry coupled to the control terminal of the second transistor driver, the second terminal of the first control circuitry coupled to the control terminal of the fourth transistor; and
second control circuitry having a first terminal and a second terminal, the first terminal of the second control circuitry coupled to the control terminal of the second transistor driver, the second terminal of the second control circuitry coupled to the control terminal of the sixth transistor.

15. The circuit of claim 14, further comprising:
a first resistor coupled between the first terminal of the second transistor and the first terminal of the sixth transistor; and
a second resistor having a first terminal and a second terminal, the first terminal of the second resistor coupled to the second terminal of the sixth transistor, the second terminal of the second resistor coupled to ground.

16. The circuit of claim 12, further comprising:
second pull-down circuitry having a first terminal, a second terminal, a third terminal, a fourth terminal, and a control terminal, the first terminal of the second pull-down circuitry coupled to the control terminal of the first transistor, the second terminal of the second pull-down circuitry coupled to ground, the third terminal of the second pull-down circuitry coupled to the control terminal of the first transistor, the fourth terminal of the second pull-down circuitry coupled to the second terminal of the first transistor, the control terminal of the second pull-down circuitry coupled to the control terminal of the second transistor driver.

17. The circuit of claim 16, wherein the second pull-down circuitry includes:
a third transistor having a first terminal, a second terminal, and a control terminal, the first terminal of the third transistor coupled to the control terminal of the first transistor, the second terminal of the third transistor coupled to the second terminal of the first transistor;
a diode having a first terminal and a second terminal, the first terminal of the diode coupled to the control terminal of the first transistor, the second terminal of the diode coupled to the control terminal of the third transistor;
a fourth transistor having a first terminal, a second terminal, and a control terminal, the first terminal of the fourth transistor coupled to the control terminal of the third transistor, the second terminal of the fourth transistor coupled to ground, the control terminal of the fourth transistor coupled to the control terminal of the second transistor driver; and
a fifth transistor having a first terminal, a second terminal, and a control terminal, the first terminal of the fifth transistor coupled to the control terminal of the first transistor, the second terminal of the fifth transistor coupled to ground, the control terminal of the fifth transistor coupled to the control terminal of the second transistor driver.

18. The circuit of claim 12, further comprising:
an inductor having a first terminal and a second terminal, the first terminal of the inductor coupled to the second terminal of the first transistor and the first terminal of the second transistor;
a voltage source coupled to the second terminal of the inductor; and
a load coupled to the first terminal of the first transistor,
wherein the second terminal of the second transistor is coupled to ground.

19. The circuit of claim 18, wherein the load includes an amplifier and a speaker coupled to the amplifier.

20. The circuit of claim 12, further comprising:
logic circuitry having an input, a first output, and a second output, the first output of the logic circuitry coupled to the control terminal of the first transistor driver, the second output of the logic circuitry coupled to the control terminal of the second transistor driver;
a modulator having a first input, a second input, and an output, the second input of the modulator coupled to a current feedback terminal, the output of the modulator coupled to the input of the logic circuitry; and
an error amplifier having a first input, a second input, and an output, the first input of the error amplifier coupled to a reference terminal, the second input of the error amplifier coupled to a voltage feedback terminal, the output of the error amplifier coupled to the first input of the modulator.
